(19) United States
(12) Patent Application Publication
(10) Pub. No.: US 2013/0087379 A1
(43) Pub. Date: Apr. 11, 2013

(54) HIGH RELIABILITY WAFER LEVEL PACKAGE AND MANUFACTURING METHOD

(71) Applicants: George Grama, Sanford, FL (US); Christophe Zinck, Grenoble (FR); Pierre-Alexandre Girard, Apopka, FL (US); Charles E. Carpenter, Orlando, FL (US)

(72) Inventors: George Grama, Sanford, FL (US); Christophe Zinck, Grenoble (FR); Pierre-Alexandre Girard, Apopka, FL (US); Charles E. Carpenter, Orlando, FL (US)

(73) Assignee: TRIQUINT SEMICONDUCTOR, INC., Hillsboro, OR (US)

(21) Appl. No.: 13/270,152

(22) Filed: Oct. 10, 2011

(51) Int. Cl. H05K 5/00; H05K 13/00

(52) U.S. Cl. 174/546; 29/592.1

(57) ABSTRACT

Disclosed embodiments include a package having an electronic device disposed within a cavity formed by an enclosure that includes a sharp portion. The package may further include a photosensitive layer applied over the enclosure to provide a smooth portion that is adjacent to the sharp portion. Methods for manufacturing the package are also described. Other embodiments may be described and claimed.

### FIELD OF THE INVENTION

Embodiments of the present disclosure generally relate to bulk acoustic wave (BAW) and surface acoustic wave (SAW) devices, and more particularly to such devices having a clean and robust air cavity styled package.

### BACKGROUND OF THE INVENTION

SAW and BAW device manufacturers are incorporating wafer-level packaging (WLP) solutions to meet the size and cost reduction demands of the wireless communications market. For proper acoustic performance, SAW and BAW devices provide a clean air cavity over an acoustically active area of a substrate. Techniques currently exist to provide a clean air cavity through the use of different types of sacrificial layers. However, such techniques may be associated with degradation of electrical performance of the SAW and BAW devices through various process and/or testing operations to which the devices may be subjected.

### BRIEF DESCRIPTION OF THE DRAWINGS

For a fuller understanding of the invention, reference is made to the following detailed description, which, taken in connection with the accompanying drawings, illustrate various embodiments of the present invention, in which:

FIG. 1 is a partial cross sectional view illustrating a wafer level package in accordance with some embodiments;

FIGS. 2 and 3 are partial cross sectional views of a wafer level package in various processing stages in accordance with some embodiments; and

FIGS. 4A-4F illustrate a cross section of structures resulting from exposing a photosensitive material to various bake temperatures in accordance with some embodiments.

### DETAILED DESCRIPTION OF THE PREFERRED EMBODIMENTS

The present invention will now be described more fully hereinafter with reference to the accompanying drawings, in which embodiments of the invention are shown. This invention may be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout.

FIG. 1 is a partial cross sectional view illustrating one embodiment of the present invention. Wafer level package 10 includes a substrate 12 (also referred to as a wafer) having a top surface 14 on which an electronic device 16 is positioned. The electronic device 16 may be a surface acoustic wave (SAW) filter or a bulk acoustic wave (BAW) filter, by way of example. An enclosure 18 is provided on the top surface 14, wherein the electronic device 16 is within a cavity 20 formed by an interior surface 22 of the enclosure 18. The enclosure 18 may include a top wall 42 and side walls 44 forming the cavity 20.

An exterior surface 24 of the enclosure 18 includes one or more sharp portion(s) 26, formed, for example, by surface portion 26a being in an angled position relative to adjacent surface portion 26b, such as sides forming corners, by way of example. The sharp portion(s) 26 may be any type of sharpness, and is not limited to sides coming together at a 90-degree angle, e.g., sharp portion(s) 26 may be formed by sides coming together at a 135-degree angle, a 90-degree angle, a 45-degree angle, or any angle. In addition, sharp portion(s) 26 need not be absolutely sharp, but only need be sufficiently sharp to benefit from the teachings of the present invention.

Developed photosensitive layer 30 encapsulates the enclosure 18. The developed photosensitive layer 30 may be secured to the exterior surface 24 of the enclosure 18 and may form a patterned shape 32 resulting from the developing of the developed photosensitive layer 30. As will be described later, the developed photosensitive layer 30 is reflowed prior to curing, such that the developed photosensitive layer 30 provides smooth portion(s) 31 on an outer surface 34. The smooth portion(s) 31 may be adjacent to sharp portion(s) 26 of the exterior surface 24 of the enclosure 18. In some embodiments, the outer surface 34 of the developed photosensitive layer 30 may be an agonic surface. Outer surface 34 smoothes out sharp portion(s) 26 of exterior surface 24 of the enclosure 18 such that the sharpness present in sharp portion 26 on exterior surface 24 of enclosure 18 is not present on the outer surface 34.

An inorganic layer 36 covers the outer surface 34 and thus takes on characteristics of the outer surface 34, thereby providing a desirable agonic and generally smooth outer surface 38. A top portion 40 of the inorganic layer 36 defined above a top wall 42 of the enclosure 18, and generally above the cavity 20, is dome shaped. The dome shape of the top portion 40 of the inorganic layer 36 may be the result of a similar dome shape of the underlying photosensitive layer 30. The dome shape of the photosensitive layer 30 may be a result of a reflow operation as discussed below.

Wafer level package 10 thus may have a domed top surface 46 that has a center portion 46C that is higher than side surface portions 46S, relative to the substrate 12 by a dome height 48 in one embodiment. This provides added strength for supporting subsequent processing of wafer level package 10, such as overmolding procedures. Enclosure 18, developed photosensitive layer 30 and inorganic layer 36 together form wafer level package 10 having a structural strength sufficient to withstand significant overmold pressures, e.g., overmold pressures up to 1000 psi.

In one embodiment, enclosure 18 is formed from a photo definable epoxy, such as, for example, a SU8 epoxy resin. Substrate 12, may be, for example, Si, GaAs, LiTaO3, LiNbO3 or glass. Inorganic layer 36 may be a rigid dielectric layer formed from a nitride material, such as, for example, silicon nitride or silicon oxi-nitride, thereby forming inorganic layer 36 as a moisture resistant layer. Developed photosensitive layer 30 may be formed from a positive resist photosensitive material, for example, AZ4330, AZ4620, AZ4999, bisbenzocyclobutene (BCB) or a polyimide material.

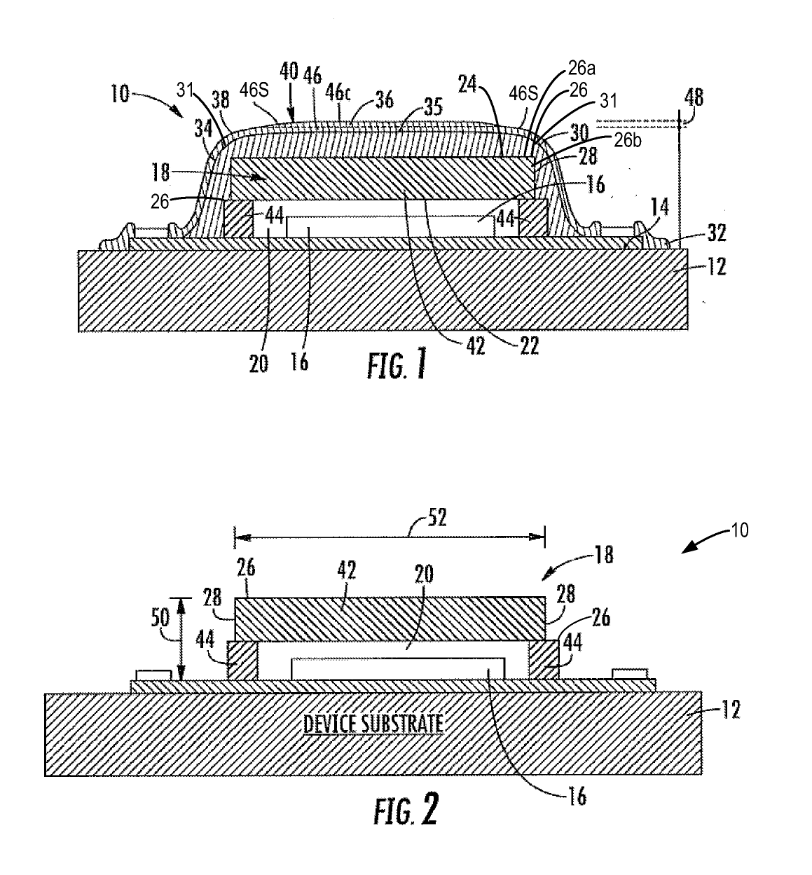

FIG. 2 is a partial cross sectional view of the wafer level package 10 in an earlier processing stage, relative to processing stage of wafer level package 10 shown in FIG. 1, according to one embodiment of the present invention. One method of producing wafer level package 10 according to one embodiment of the present invention includes providing a substrate 12 already having on its top surface 14 an electronic device 16 within a cavity 20 formed by an enclosure 18. Enclosure 18 may be formed by using various fabrication processes, e.g., patterning, deposition, removal, etc. As described above, exterior surface 24 of the enclosure 18 includes sharp portion(s) 26. In some embodiments, a smoothing overcoat layer is provided in order to reduce stress over relatively high-aspect-ratio cavity enclosures 18. As used herein, the aspect ratio refers to the ratio of height 50 to width 52 of the enclosure 18.

FIG. 3 is a partial cross sectional view of the wafer level package 10 in another processing stage, subsequent to processing stage of FIG. 2 and prior to processing stage of FIG. 1, according to one embodiment of the present invention. One method according to one embodiment of the present invention includes applying a photosensitive layer onto the exterior surface 24 of enclosure 18, to provide an overcoat, and developing the photosensitive layer to define a pattern 32 in the developed photosensitive layer 30. Pattern 32 may be established to accommodate pads and cut street openings on substrate 12 having multiple packages.

In one embodiment of the present invention, heat is applied to the developed photosensitive layer 30, permitting the material forming developed photosensitive layer 30 to reflow and form the outer surface 34 as, e.g., an agonic surface. As a result, the sharp portion(s) 26 of exterior surface 24 are covered by developed photosensitive layer 30 that now has smooth outer surface 34. As a result of the reflow baking operation, the outer surface 34 may take on a dome shape 35 above the cavity 18. The reflowed developed photosensitive layer 30 is then cured to form a hardened overcoat having the outer surface 34, resulting in the formative stage of the wafer level package 10 illustrated in FIG. 3.

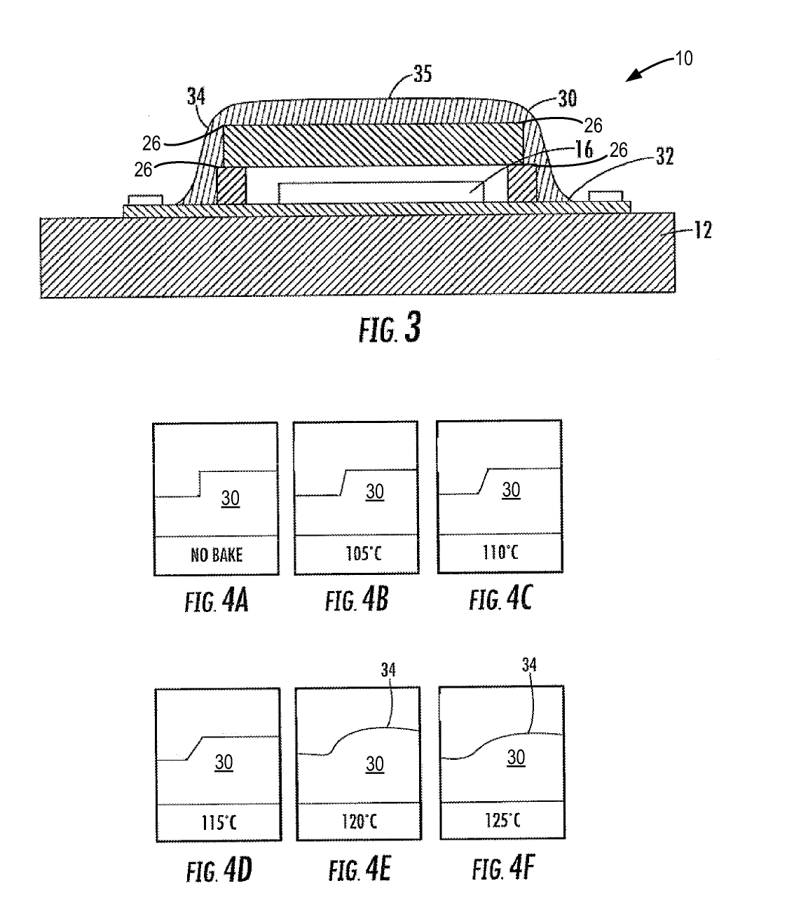

FIGS. 4A-4F illustrate an example of smoothing out edges of a developed photosensitive layer, according to one embodiment of the present invention. FIGS. 4A-4F illustrate smoothing out sharp corners of the developed photosensitive layer 30, which may be present upon initial application of the developed photosensitive layer 30, during reflow of developed photosensitive layer 30, to provide an agonic outer surface 34. Once the developed photosensitive layer 30 has been reflowed to a desired degree, it may be cured, for example, by hard UV curing prior to a hard baking, to provide a full cross-linking of the developed photosensitive layer 30 to prevent further movement (e.g., smoothing) from occurring with subsequent use.

The reflowing of developed photosensitive layer 30 will smooth the sharp portion(s) to various degrees depending upon the temperatures applied, as illustrated with reference to FIGS. 4A-4F for AZ ECI 3000 photosensitive material, by way of example.

Developed photosensitive layer 30 may be applied through a spin coating process, a spray coating process, a dry film laminating process, or other processes. Prior to applying the developed photosensitive layer 30, enclosure 18 and exposed portions of substrate 12 may be cleaned to enhance dielectric adhesion of developed photosensitive layer 30 to enclosure 18 and exposed portions of the substrate 12.

Following the processing stage of FIG. 3, the inorganic layer 36 may be applied to the developed photosensitive layer 30 to provide the wafer level package 10 with a rigid hermetic seal and to improve the overall structural integrity of the wafer level package 10. In various embodiments, the inorganic layer 36 may be, but is not limited to, a hard nitride/oxide coating. The developed photosensitive layer 30 may improve uniformity of the inorganic layer 36, thereby improving its hermetic and structural integrity properties.

Inorganic layer 36 may be deposited by, for example, microelectronics techniques, such as plasma enhanced chemical vapor deposition (PECVD), PVD, a chemical solution deposition referred to as sol gel, and the like.

Now protected, the electronic device 16 may be capable of withstanding a variety of process and/or testing operations, such as, for example, mold transfer, and autoclave or Hast tests. Embodiments of the present invention may be compatible with, for example, chip and wire assembly processes and bumping processes. In addition, wafer level package 10 may be ready, for example, to be diced, taped, reeled and directly assembled on a laminate board.

While embodiments of the present disclosure are described with respect to acoustic wave filters, e.g., BAW and SAW filters, other embodiments may include other types of devices that benefit from the described clean and robust air-cavity packages. For example, packages of other embodiments may be used in microelectromechanical systems (MEMS), micro-fluidic MEMS, nanoelectromechanical systems (NEMS), etc.

Many modifications and other embodiments of the invention will come to the mind of one skilled in the art having the benefit of the teachings presented in the foregoing descriptions and the associated drawings. Therefore, it is understood that the invention is not to be limited to the specific embodiments disclosed, and that modifications and embodiments are intended to be included within the scope of the appended claims.

That which is claimed is:

1. A package comprising:
a substrate having a top surface;
an electronic device positioned on the top surface;
an enclosure provided on the top surface, wherein the electronic device is within a cavity formed by the enclosure, and wherein a surface of the enclosure includes a sharp portion; and
a developed photosensitive layer encapsulating the enclosure, wherein the developed photosensitive layer is reflowed to provide a smooth portion, on a surface of the developed photosensitive layer, adjacent to the sharp portion of the surface of the enclosure.

2. The package of claim 1, wherein the developed photosensitive layer comprises an agonic outer surface.

3. The package of claim 1, further comprising an inorganic layer covering the developed photosensitive layer.

4. The package of claim 3, wherein the developed photosensitive layer and the inorganic layer are dome shaped.

5. The package of claim 3, wherein a combination of the enclosure, developed photosensitive layer and inorganic layer has a structural strength sufficient to withstand an overmold pressure up to 1000 pounds per square inch.

6. The package of claim 3, wherein the inorganic layer comprises a nitride material.

7. The package of claim 6, wherein the nitride material comprises silicon nitride or silicon oxi-nitride, and wherein the inorganic layer is moisture resistant.

8. The package of claim 3, wherein the inorganic layer comprises a rigid dielectric layer.

9. The package of claim 1, wherein the developed photosensitive layer is formed from a positive resist photosensitive material.

10. The package of claim 1, wherein the developed photosensitive layer is formed from at least one of AZ4330, AZ4620, AZ4999, BCB, or a polyimide material.

11. The package of claim 1, wherein the electronic device comprises an acoustic wave device.

12. The package of claim 1, wherein:
the enclosure includes side walls and a top wall; and
the developed photosensitive layer is dome shaped over the top wall.

13. The package of claim 1, wherein the substrate is selected from a group consisting of Si, GaAs, LiTaO3, LiNbo3 and a glass.

14. The package of claim 1, wherein the enclosure comprises a photo definable epoxy.

15. A method comprising:
providing an electronic device within a cavity formed by an enclosure and a substrate, wherein a surface of the enclosure includes a sharp portion;
applying a photosensitive material on the surface of the enclosure; and
reflowing the photosensitive material to provide a smooth portion that is adjacent to the sharp portion of the surface of the enclosure.

16. The method of claim 15, wherein said reflowing the photosensitive material comprises reflowing the photosensitive material to provide the photosensitive material with an agonic surface.

17. The method of claim 15, further comprising:
applying an inorganic layer onto the photosensitive material.

18. The method of claim 17, further comprising:
providing the inorganic layer with a dome shape by said applying of the photosensitive material and/or applying of the inorganic layer.

19. The method of claim 17, further comprising:
hermetically sealing the cavity by said applying of the inorganic layer.

20. The method of claim 15, further comprising:
curing, after said reflowing, the photosensitive material.
